(19) United States
(12) Patent Application Publication
(10) Pub. No.: US 2008/0112142 A1
(43) Pub. Date: May 15, 2008

(54) MEMORY MODULE COMPRISING MEMORY DEVICES

(76) Inventors: Siva RaghuRam, Germering (DE); Simon Muff, Mering (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/558,840

(22) Filed: Nov. 10, 2006

(51) Int. Cl. H05K 1/16; H05K 7/00

(52) U.S. Cl. 361/736; 361/748; 361/782

(57) ABSTRACT

A memory module comprises a printed circuit board with a main surface bounded by a first side and a second side, the first side being longer than the second side, a first and a second generally rectangular memory device each having a long side and a short side, the first and second memory devices positioned on the main surface of the printed circuit board in such a way that the first memory device long side is generally parallel to the printed circuit board first side and the second memory device long side is generally perpendicular to the printed circuit board first side, and a first set of passive components connected to the first memory device and a second set of passive components connected to the second memory device, the first and second sets of passive components positioned on the main surface of the printed circuit board between the first memory device and interconnection pads.

### BACKGROUND OF THE INVENTION

1. Field of the Invention

The present invention relates to a memory module comprising memory devices, in particular to a very low profile memory module comprising memory devices. The present invention further relates to a printed circuit board.

2. Description of the Related Art

Modern computer systems must meet ever increasingly challenging requirements, set by the ongoing progress of information technology. Said requirements mainly translate into ever increasing computing power and ever increasing storage capacity for electronic data memories. As far as the latter electronic data memories are concerned, the computer industry has established the so-called DRAM (Dynamic Random Access Memory) as an economic means for high speed and high capacity storage for large amounts of information.

Although a DRAM requires continuous refreshing of the stored information, speed and information density, combined with relatively low cost, have put the DRAM to a pivotal position in the field of information technology. Almost every modern computer system, ranging for example from PDAs over notebooks and desktop computers to high-end servers, takes advantage of this economic and fast data storing concept.

Above all, the already mentioned server systems require large storage capacity combined with high speed, and DRAM devices may therefore be optimized for server applications. A plurality of DRAM devices are compiled on a printed circuit board to form a standardized memory module, such as a DIMM (Dual Inline Memory Module). These memory modules are then connected to further computing and processing hardware by means of detachable sockets. In this way, the memory of a computer system may easily be expanded by simply adding further memory modules or by replacing memory modules with memory modules that store more data.

Besides the DIMM, the so-called very low profile DIMM (VLP-DIMM) has been established by the semiconductor and computer industry for special applications, where space is very limited. Therein a single memory module must not exceed a certain height and width, thereby enabling high package density of entire computer systems. Such systems then allow for a higher integration, and, furthermore, complete and powerful server computers may fit into a slim and standardized chassis. The space on such a VLP module is very limited. Apart from the DRAM devices, other supportive electronic entities, such as passive components, have to be integrated onto the printed circuit board of a respective memory module. Those passive components may be useful to facilitate undisturbed signal flow and related suppression of electromagnetic interference. A prominent example for such passive components are termination resistors or capacitors for impedance matching.

Since the overall capacity of a memory module is determined by the capacitance of the applied DRAM devices and by the number of individual DRAM devices, it is desirable to increase the memory capacity of a single device, as well as to increase the number of devices on one module. However, achieving this objective is hindered by the fact that modern DRAM devices with higher capacity may also require larger and/or a rectangular foot print, i.e. a foot print different from a square-like foot print. In conjunction with the necessary placement of passive components and interconnections pads (e.g. pins), required for connectivity to the main board, the large and rectangular foot print of single DRAM devices may pose restrictions to the maximum number of memory devices which can be fit on a data memory module. This may also pose severe limits to the maximum achievable capacitance of a VLP-DIMM.

### SUMMARY OF THE INVENTION

Various aspects of the present invention can provide particular advantages for an improved memory module, an improved very low profile memory module, and an improved printed circuit board.

According to a first aspect of the invention, a memory module comprises a printed circuit board with a main surface bounded by a first side and a second side, the first side being longer than the second side, the first side further comprising a plurality of interconnection pads. Furthermore, a first and a second generally rectangular memory device are provided each having a first device side and a second device side, wherein the first device side is longer than the second device side, the first and second memory devices positioned on the main surface of the printed circuit board in such a way that the first device side of the first memory device is generally parallel to the printed circuit board first side and the first device side of the second memory device is generally perpendicular to the printed circuit board first side. A first set of passive components is connected to the first memory device and a second set of passive components is connected to the second memory device, the first and second sets of passive components positioned between the first memory device and the interconnection pads.

According to a second aspect of the invention, a printed circuit board comprises a main surface bounded by a first side and a second side, the first side being longer than the second side, the first side further comprising a plurality of interconnection pads. A first set of landing pads is positioned within a first field of the printed circuit board, the first field having a long side and a short side, wherein the long side is generally parallel to the printed circuit board first side. A second set of landing pads is positioned on a second field on the main surface of the printed circuit board, the second field having a long side and a short side, wherein the long side is generally perpendicular to the printed circuit board first side. A third set of landing pads is positioned between the first field and the interconnection pads, the third set of landing pads connected to the first set of landing pads. A fourth set of landing pads is positioned between the first field and the interconnection pads, the fourth set of landing pads connected to the second set of landing pads.

According to a third aspect of the invention a very low profile memory module comprises a printed circuit board comprising a main surface bounded by a first side and a second side, wherein the first side of the printed circuit board is between about 133 mm and 134 mm long and the second side of the printed circuit board is between about 18 mm and 19 mm long, the first side further comprising a plurality of interconnection pads. At least seven generally rectangular first memory devices and at least two generally rectangular second memory devices are provided, each memory device having a long side and a short side, the first and second memory devices positioned on the main surface of the printed circuit board such that each first memory device long side is generally parallel to the printed circuit board first side and each second memory device long side is generally perpendicular to the printed circuit board first side. A first set of passive components is connected to the first memory device and a second set of passive components is connected to the second memory device, the first and second sets of passive components positioned between the first memory device and the interconnection pads. A first signal line connects a first contact pad of one of the memory devices to a first contact pad of another of the memory devices and a second signal line connects a second contact pad of one of the memory devices to a second contact pad of another of the memory devices, wherein the first signal line and the second are of equal length.

According to a fourth aspect of the invention a main printed circuit board in an electronic device contains a microcontroller, an input/output device, sockets for accepting additional boards and signal lines for interconnecting the microcontroller the input/output device and the sockets. One of said sockets includes a memory module, said memory module comprising a printed circuit board comprising a main surface bounded by a first side and a second side, the first side being longer than the second side, the first side further comprising a plurality of interconnection pads, a first and a second generally rectangular memory device each having a long side, a short side and a set of contact pads, the first and second memory devices positioned on the main surface of the printed circuit board such that the first memory device long side is generally parallel to the printed circuit board first side and the second memory device long side is generally perpendicular to the printed circuit board first side and a first set of passive components connected to the first memory device and a second set of passive components connected to the second memory device, the first and second sets of passive components positioned between the first memory device and the interconnection pads.

### BRIEF DESCRIPTION OF THE DRAWINGS

These above recited features of the present invention will become clear from the following description, taken in conjunction with the accompanying drawings. It is to be noted, however, that the accompanying drawings illustrate only typical embodiments of the present invention and are, therefore, not to be considered limiting of the scope of the invention. The present invention may admit other equally effective embodiments.

FIG. 1 shows a schematic view of a memory module, according to a first embodiment of the present invention;

FIG. 2 shows a schematic view of a printed circuit board, according to the first embodiment of the present invention;

FIG. 3 shows a schematic view of a memory module, according to a second embodiment of the present invention;

FIG. 4A show a schematic view of a connection scheme between two contact pads according to a third embodiment of the present invention;

FIG. 4B show a schematic view of a connection scheme between two contact pads according to a fourth embodiment of the present invention; and

FIG. 5 shows a schematic view of a main printed circuit board in an electronic device, according to a fifth embodiment of the present invention.

### DETAILED DESCRIPTION OF THE PREFERRED EMBODIMENT

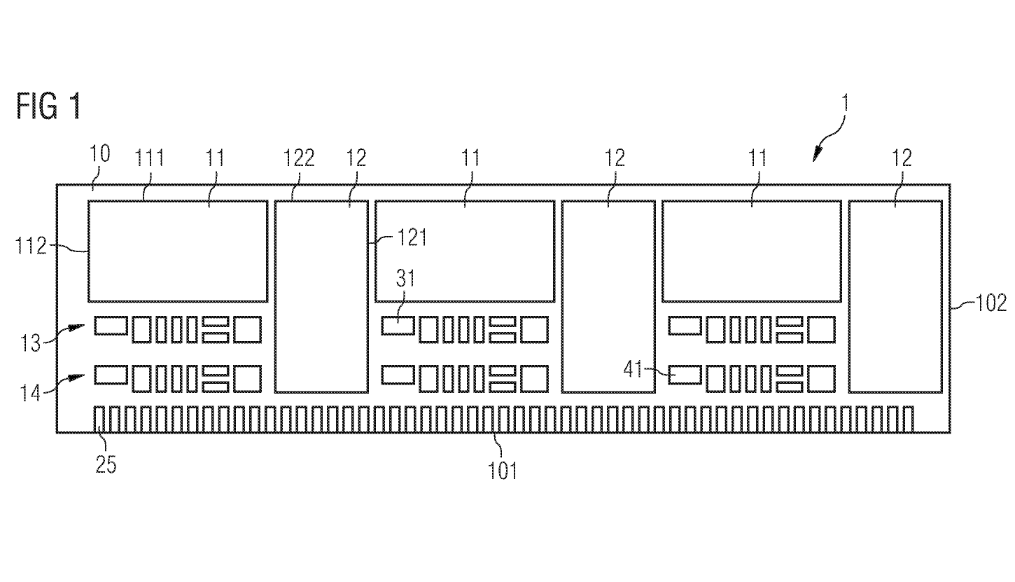

FIG. 1 schematically shows a memory module 1 according to a first embodiment of the present invention, comprising a printed circuit board with a main surface 10 carrying active and passive components, such as a first memory device 11, a second memory device 12 and passive components 31, 41. Said printed circuit board main surface 10 is bounded by a first side 101 and a second side 102, said first side 101 being longer than said second side 102. Furthermore, said first memory device 11 is bounded by a long side 111 and a short side 112, said long side 111 being longer than said short side 112. Said first memory device 11 is arranged on a printed circuit board main surface 10 in such a way that the first memory module long side 111 is parallel to the printed circuit board first side 101. Said second memory device 12 is bounded by a long side 121 and a short side 122, said long side 121 being longer than said short side 122. Said second memory device 12 is arranged on the printed circuit board main surface 10 in such a way that the second memory device long side 121 is perpendicular to said printed circuit board first side 101.

Both the first and the second memory device 11, 12 are of the same size and have a generally rectangular foot print, i.e. a non-square foot print since their respective long sides 111, 121 are longer than their respective short sides 112, 122. An example for a DRAM memory device having a rectangular foot print is a 1 GB DRAM chip.

The first memory device 11 and the second memory device 12 are arranged on the printed circuit board main surface 10 in such a way that their respective long sides 111, 121 are perpendicular to each other in order to be able to assemble an extended number of memory devices onto the printed circuit board main surface 10, and hence to increase the overall memory capacity of the memory module 1.

Interconnection pads 25 are arranged on the printed circuit board main surface 10 along one of the its first sides 101 and may reach up to an edge of the printed circuit board. The printed circuit board may also comprise notches and/or other means (not shown) for fitting the memory module 1 into a socket for proper connection of the memory module 1 to other computing components, such as a mother board with central processing units, via the interconnection pads 25.

A first set 13 of passive components 31 and a second set 14 of passive components 41 are arranged between the first memory device 11 and the interconnection pads 25. This passive component arrangement enables the second memory device 12 to be placed with its short sides 122 along the first sides 101 of the memory module 1. Hence the second memory module 12 requires a reduced lateral space with respect to the first sides 101 of the printed circuit board main surface 10. Because the second set 14 of passive components 41 that are connected to the second memory device 12 is placed between the first memory device 11 and the interconnection pads 25, the second memory device 12 can be arranged directly adjacent to the interconnection pads 25. Therefore, almost the entire printed circuit board second side 102 is available for the foot print of the second memory device 12.

The printed circuit board main surface 10 may carry memory devices 11, 12, passive components 31, 41, and interconnection pads 25 on both the top and the bottom surface, thus carrying up to twice the number of components and devices as shown in FIG. 1.

The first set 13 of passive components 31 and second sets 14 of passive components 41 are positioned between the first memory device 11 and the interconnection pads 25 are located on the main surface 10 of the printed circuit board. Alternatively, the first set 13 of passive components 31 and second sets 14 of passive components 41 are positioned between the first memory device 11 and the interconnection pads 25 are buried under the main surface of the printed circuit board.

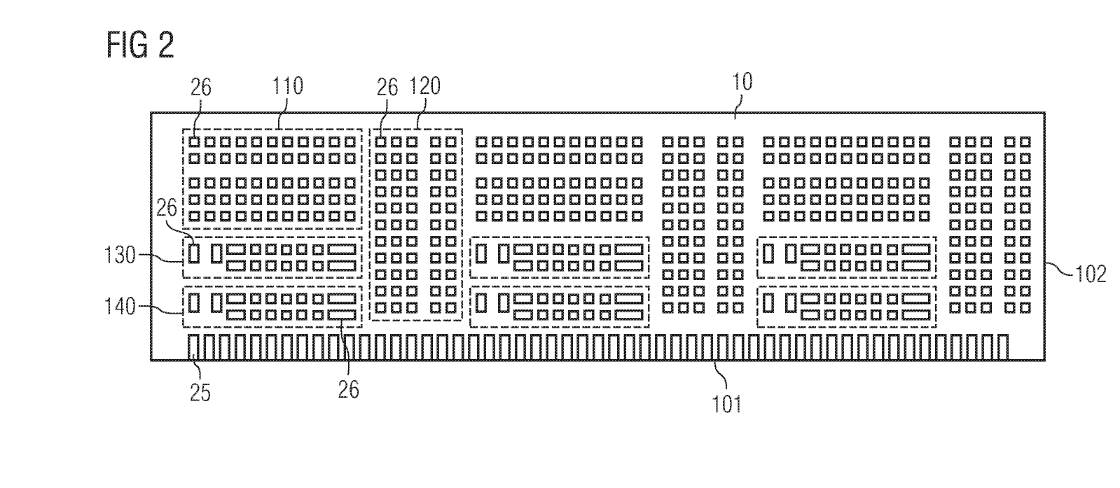

FIG. 2 shows a schematic view of the top surface of the printed circuit board main surface 10. The printed circuit board main surface 10 comprises landing pads 26 and the interconnection pads 25 on the top surface. The printed circuit board main surface 10 may also comprise landing pads and interconnection pads for holding active and passive components and for interconnection on the bottom surface (not shown). The landing pads 26 are arranged within a first field 110 and a second field 120 for being connected to contact pads of the memory devices, such as the first and second memory devices 11, 12, described in FIG. 1. Each of the first field 110 and the second field 120 is bounded by a long side and a short side.

The arrangement of the landing pads 26 within the first field 110 matches the arrangement of the landing pads 26 within the second field 120. Hence memory devices with identical pin-out layouts may be mounted on the first field 110 of landing pads 26 and on the second field 120 of landing pads 26.

Furthermore, landing pads 26 are arranged within a third field 130 and a fourth field 140 in order to be connected to the passive components 41, 31 described in FIG. 1. The third field 130 of landing pads 26 and the fourth field 140 of landing pads 26 are arranged between the first field 110 of landing pads 26 and the interconnection pads 25 on the printed circuit board main surface 10. This allows for the arrangement of the second field 120 of landing pads 26 on the printed circuit board main surface 10 to be rotated by 90° with respect to the first field 110. In consequence, the long side of the first field 110 is generally perpendicular to the printed circuit board first side 102 and the long side of the second field 120 is generally parallel to the printed circuit board first side 102.

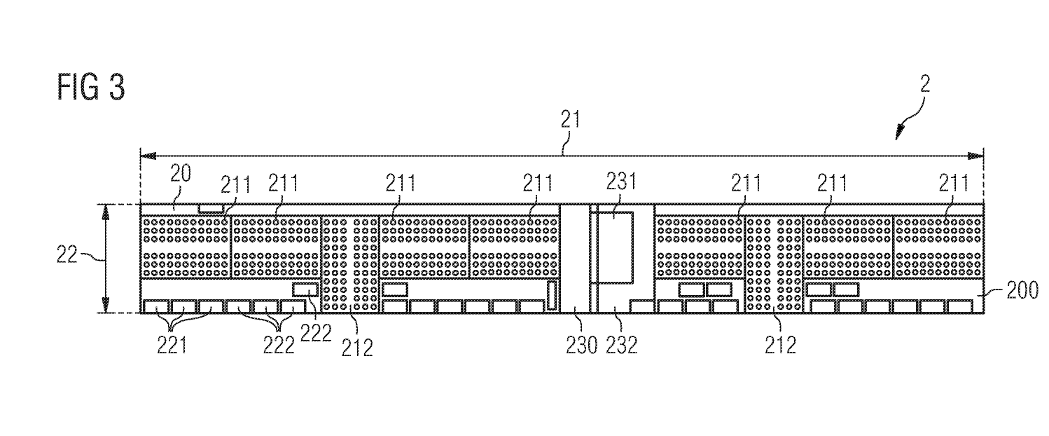

FIG. 3 shows a memory module 2 according to a second embodiment of the present invention. The memory module 2 may be a very low profile DIMM (VLP-DIMM) having a length 21 of a first side being in the range from 133 mm to 134 mm, and having a height 22 of a second side being in the range from 18 mm to 19 mm. The memory module 2 comprises at least seven first generally rectangular memory devices 211 and two second generally rectangular memory devices 212. The position of contact pads of the generally rectangular memory devices 211, 212 is indicated by the array of circles. The contact pads are connected to landing pads (not shown) of a printed circuit board main surface 20.

Said first generally rectangular memory devices 211 are arranged on the printed circuit board main surface 20 in such a way that their long sides are parallel to the lateral extension of the printed circuit board main surface 20, i.e. the length 21. The second generally rectangular memory devices 212 are arranged on the printed circuit board 20 in such a way that their short sides are parallel to the lateral extension of the printed circuit board main surface 20, i.e. the length 21. First passive components 221 being connected to the first memory devices 211 and second passive components 222 being connected to the second memory devices 212 are arranged between one long side of the printed circuit board main surface 20 and the first memory devices 211. Furthermore, interconnection pads (not shown) are arranged at the one long side of the printed circuit board main surface 20.

According to the arrangement shown in FIG. 3 the second memory module 212 requires a reduced lateral space with respect to the length 21 of the printed circuit board main surface 10. Hence, at least 9 generally rectangular memory devices 211, 212 fit along the length 21 of the memory module 2, i.e. leading to at least 18 generally rectangular memory devices in case of memory modules being mounted on both the top and the bottom surfaces of the printed circuit board main surface. In consequence the overall memory capacitance of the memory module 2 is increased. The generally rectangular memory devices 211, 212 fit onto the printed circuit board main surface 20 without requiring buried or printed resistors. However buried or printed resistors may be included, if desired. This substantially eases the manufacturing of the printed circuit board and also leads to both an improved production yield and a higher reliability for the memory module 2.

In the illustrative embodiment, the memory module 2 further comprises memory controllers 230, 232 and a phase locked loop 231 (PLL) as shown in FIG. 3. The memory controllers 230, 232 may be memory controllers such as controller 32871 or controller 32869, whereas the phase locked loop controller 231 may be a PLL 877.

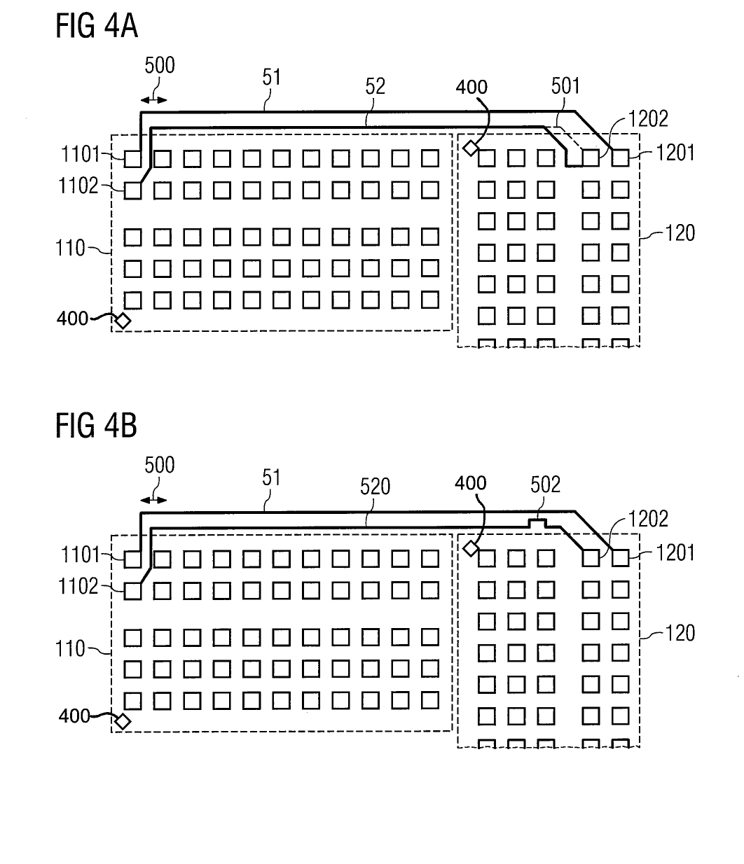

FIG. 4A shows a schematic view of the routing of connections between landing pads on the printed circuit board main surface 10 according to a third embodiment of the present invention. As described with respect to FIG. 2, the generally rectangular first field 110 of landing pads is arranged perpendicularly to the generally rectangular second field 120 of landing pads. The arrangement of the landing pads within the first field 110 is the same as the arrangement of the landing pads within the second field 120 as to allow for the connection of memory devices with an identical pin-out arrangement. The orientation of the fields 110, 120 of landing pads is indicated by black diamond 400 orientation marks.

A first landing pad 1101 and a second landing pad 1102 of the first field 110 and a first landing pad 1201 and a second landing pad 1202 of the second field 120 are arranged at corresponding positions within the first field 110 and the second field 120 with respect to the respective black diamond 400 orientation marks. A first signal line 51 connects the first landing pad 1101 of the first field 110 to the first landing pad 1201 of the second field 120. A second signal line 52 connects the second landing pad 1102 of the first field 110 to the second landing pad 1202 of the second field 120. Routing of signal lines 51 and 52 is carried out while keeping the respective length of the signal lines 51, 52 as short as possible and while avoiding line crossings. Line crossings may require so-called vias and routing of the respective signal lines on more than one layer. The conventional method of routing signal lines on more than one layer by means of vias for contacting signal lines between two layers may be employed for routing the signal lines 51, 52 as well, but is not described here in greater detail.

As shown in FIG. 4A, if precise matching of the signal delay is desired as to minimize data or clock skews, the length of the first signal line 51 matches the length of the second signal line 52 by adjusting the course of the second signal line 52. The shortest routing of second signal line 52 would lead to a second signal line layout with a connection stub 501 towards the second landing pad 1202 of the second field 120 shown as a dotted line in FIG. 4A. Such a routing however would result in the first signal line 51 being longer than the second signal line 52 by an additional length 500. To achieve equal signal line lengths of the first signal line 51 and the second signal line 52, the routing of the second signal line 52 is extended in the vicinity of the second landing pad 1202 as shown in FIG. 4A. Alternatively, any other routing for rendering the lengths of signal lines 51 and 52 equal may be employed herein as well.

The equal lengths of two corresponding signal lines, such as the first signal line 51 and the second signal line 52, may be required to achieve well-defined and equal fly times of signals being routed between first landing pads 1101, 1201 and between second landing pads 1102, 1202, respectively. In memory modules, the well-defined and equal signal fly times are typically important for a data flow between memory devices without data collision, delay cycles, additional signal routing or data scrambling. With the layout shown in FIG. 4A, equal signal fly times are achieved although the first field 110 of landing pads is arranged perpendicularly to the second field 120 of landing pads. Hence, the requirement of well-defined and equal signal fly times is met while still being able to arrange an extended number of memory devices on a memory module.

FIG. 4B shows an alternative connection layout of the first landing pad 1101 and the second landing pad 1102 of the first field 110 and the first landing pad 1201 and a second landing pad 1202 of the second field 120. According to a fourth embodiment of the present invention shown in FIG. 4B a second signal line 520 connecting the second landing pad 1102 of the first field 110 and the second landing pad 1202 of the second field 120 comprises a meandering loop 502 to match the length of the first signal line 51, connecting the first landing pad 1101 of the first field 110 and the second landing pad 1201 of the second field 120.

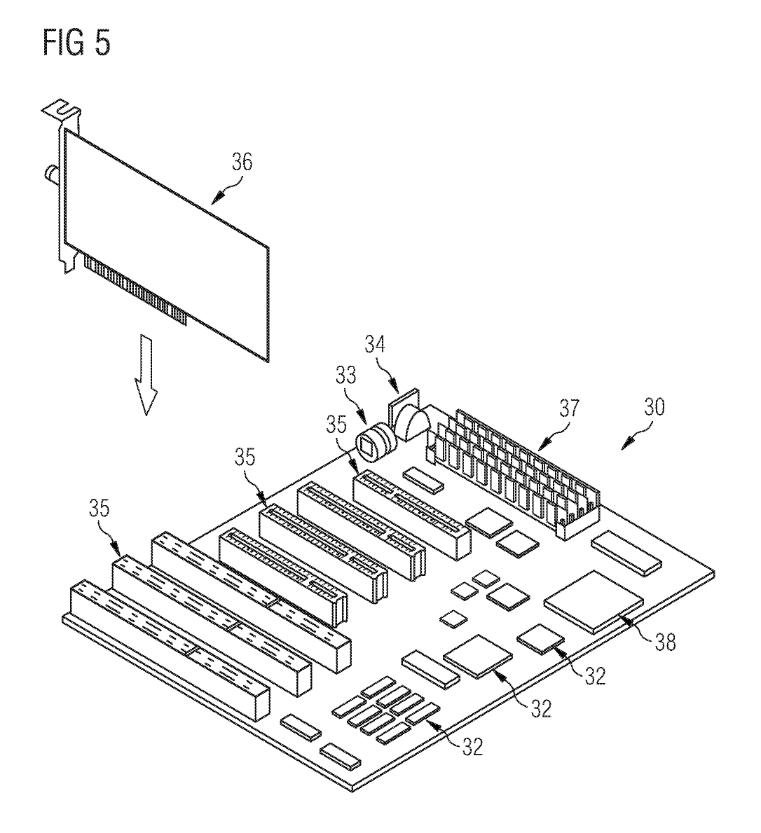

FIG. 5 schematically shows a main printed board 30 in a electronic device. Such a main printed board may be a motherboard included in a micro computer. The main printed board 30 contains a microcontroller 38 and further controllers 32 required to control peripheral devices such as display screens, keyboards and printers. Moreover, an energy supply device 33 such as a battery is located on the main printed board. The main printed board is further provided the input output devices 34 such as keyboard connector. Moreover, different types of sockets 35 for accepting additional boards such as extension boards 36 reside on the printed circuit board. One type of socket as shown in FIG. 5 contains memory modules 37 as disclosed in FIGS. 1 to 4.

The routing of connections between landing pads on the printed circuit board main surfaces disclosed with respect to FIGS. 4A and 4B may be applied to the printed circuit board main surfaces disclosed with respect to FIGS. 1, 2 and 3. The preceding description describes advantageous exemplary embodiments of the invention. The features disclosed therein and the claims and the drawings can, therefore, be useful for realizing the invention in its various embodiments, both individually and in any combination. While the foregoing is directed to embodiments of the present invention, other and further embodiments of this invention may be devised without departing from the basic scope of the invention, the scope of the present invention being determined by the claims that follow.

What is claimed is:

1. A memory module, comprising:
a printed circuit board comprising a main surface bounded by a first side and a second side, the first side being longer than the second side, the first side further comprising a plurality of interconnection pads;
a first and a second generally rectangular memory device each having a first device side, a second device side shorter than the first device side, and a set of contact pads, the first and second memory devices positioned on the main surface of the printed circuit board such that the first device side of the first memory device is generally parallel to the printed circuit board first side and the first device side of the second memory device is generally perpendicular to the printed circuit board first side, and
a first set of passive components connected to the first memory device and a second set of passive components connected to the second memory device, the first and second sets of passive components positioned between the first memory device and the interconnection pads.

2. The memory module of claim 1 wherein the first and second sets of passive components positioned between the first memory device and the interconnection pads are located on the main surface of the printed circuit board.

3. The memory module of claim 1 wherein the first and second sets of passive components positioned between the first memory device and the interconnection pads are buried under the main surface of the printed circuit board.

4. The memory module of claim 1 wherein the first and the second memory device are of the same size and the set of contact pads is positioned on a bottom side of each of the first and the second memory devices.

5. The memory module of claim 4 wherein the printed circuit board comprises a first signal line and a second signal line, the first signal line connecting a first contact pad of the set of contact pads of the first memory device to a first contact pad of the set of contact pads of the second memory device and the second signal line connecting a second contact pad of the set of contact pads of the first memory device to a second contact pad of the set of contact pads of the second memory device.

6. The memory module of claim 5 wherein the first signal line and the second signal line are of equal length.

7. The memory module of claim 6 wherein the second signal line comprises a meandering loop.

8. The memory module of claim 1 wherein the first side of the printed circuit board is between about 133 mm and 134 mm long and the second side of the printed circuit board is between about 18 mm and 19 mm long.

9. A printed circuit board comprising:
a main surface bounded by a first side and a second side, the first side longer than the second side, the first side further comprising a plurality of interconnection pads;
a first set of landing pads positioned within a first field of the printed circuit board, the first field having a long side and a short side shorter than the long side, wherein the long side is generally parallel to the printed circuit board first side;
a second set of landing pads positioned on a second field on the main surface of the printed circuit board, the second field having a long side and a short side, wherein the long side is generally perpendicular to the printed circuit board first side;
a third set of landing pads positioned on the main surface of the printed circuit board between the first field and the interconnection pads, the third set of landing pads connected to the first set of landing pads; and
a fourth set of landing pads positioned between the first field and the interconnection pads, the fourth set of landing pads connected to second set of landing pads.

10. The printed circuit board of claim 9 wherein the arrangement of the first set of landing pads within the first field matches the arrangement of the second set of landing pads within the second field.

11. The printed circuit board of claim 10 wherein the printed circuit board comprises a first signal line and a second signal line, the first signal line connecting a first landing pad of the first set of landing pads to a first landing pad of the second set of landing pads and the second signal line connecting a second landing pad of the first set of landing pads to a second landing pad of the second set of landing pads, and wherein the position of the first landing pad within the first field matches the position of the first landing pad within the second field and the position of the second landing pad within the first field matches the position of the second landing pad within the second field.

12. The printed circuit board of claim 11 wherein the first signal line and the second signal line are of equal length.

13. The printed circuit board of claim 12 wherein the second signal line comprises a meandering loop.

14. The printed circuit board of claim 13 wherein the first side of the printed circuit board is between about 133 mm and 134 mm long and the second side of the printed circuit board is between about 18 mm and 19 mm long.

15. A very low profile memory module, comprising:
a printed circuit board comprising a main surface bounded by a first side and a second side, wherein the first side of the printed circuit board is between about 133 mm and 134 mm long and the second side of the printed circuit board is between about 18 mm and 19 mm long, the first side further comprising a plurality of interconnection pads;
at least seven generally rectangular first memory devices and at least two generally rectangular second memory devices, each memory device having a long side and a short side, the first and second memory devices positioned on the main surface of the printed circuit board such that each first memory device long side is generally parallel to the printed circuit board first side and each second memory device long side is generally perpendicular to the printed circuit board first side;
a first set of passive components connected to the first memory device and a second set of passive components connected to the second memory device, the first and second sets of passive components positioned between the first memory device and the interconnection pads;
a first signal line connecting a first contact pad of one of the memory devices to a first contact pad of another of the memory devices; and
a second signal line connecting a second contact pad of one of the memory devices to a second contact pad of another of the memory devices, wherein the first signal line and the second are of equal length.

16. The memory module of claim 15 wherein the first and second sets of passive components positioned between the first memory device and the interconnection pads are located on the main surface of the printed circuit board.

17. The memory module of claim 15 wherein the first and second sets of passive components positioned between the first memory device and the interconnection pads are buried under the main surface of the printed circuit board.

18. The memory module of claim 15 wherein the first memory devices and the second memory devices are of the same size.

19. The memory device of claim 18 wherein the second signal line comprises a meandering loop.

20. A main printed circuit board in an electronic device, comprising:
a microcontroller;
an input/output device;
sockets for accepting additional boards; and
signal lines for interconnecting the microcontroller the input/output device and the sockets;
one of said sockets including a memory module, said memory module comprising:
a printed circuit board comprising a main surface bounded by a first side and a second side, the first side being longer than the second side, the first side further comprising a plurality of interconnection pads,
a first and a second generally rectangular memory device each having a long side, a short side shorter than the long side and a set of contact pads, the first and second memory devices positioned on the main surface of the printed circuit board such that the first memory device long side is generally parallel to the printed circuit board first side and the second memory device long side is generally perpendicular to the printed circuit board first side, and
a first set of passive components connected to the first memory device and a second set of passive components connected to the second memory device, the first and second sets of passive components positioned between the first memory device and the interconnection pads.

21. The main printed circuit board of claim 20 wherein the first and second sets of passive components positioned between the first memory device and the interconnection pads are located on the main surface of the printed circuit board of the memory module.

22. The main printed circuit board of claim 20 wherein the first and second sets of passive components positioned between the first memory device and the interconnection pads are buried under the main surface of the printed circuit board of the memory module.

23. The main printed circuit board of claim 20 wherein the first and the second memory device of the memory module are of the same size and the set of contact pads is positioned on a bottom side of each of the first and the second memory devices.

24. The main printed circuit board of claim 23 wherein the printed circuit board of the memory module comprises a first signal line and a second signal line, the first signal line connecting a first contact pad of the first memory device set of contact pads to a first contact pad of the second memory device set of contact pads and the second signal line connecting a second contact pad of the first memory device set of contact pads to a second contact pad of the second memory device set of contact pads.

25. The main printed circuit board of claim 24 wherein the first signal line and the second signal line of the memory module are of equal length.

26. The main printed circuit board of claim 25 wherein the second signal line of the memory module comprises a meandering loop.

27. The main printed circuit board of claim 20 wherein the first side of the printed circuit board of the memory module is between about 133 mm and 134 mm long and the second side of the printed circuit board is between about 18 mm and 19 mm long.
